(19) United States
(12) Patent Application Publication
(10) Pub. No.: US 2023/0274942 A1
(43) Pub. Date: Aug. 31, 2023

(54) METHOD FOR MANUFACTURING SEMICONDUCTOR DEVICE

(71) Applicant: KIOXIA CORPORATION, Tokyo (JP)

(72) Inventors: Hiroshi NAMBU, Yokkaichi Mie (JP); Junichi HASHIMOTO, Yokkaichi Mie (JP); Tsubasa IMAMURA, Kuwana Mie (JP)

(21) Appl. No.: 17/902,751

(22) Filed: Sep. 2, 2022

(30) Foreign Application Priority Data
Feb. 28, 2022 (JP) 2022-029922

(51) Int. Cl. H01L 21/311

(52) U.S. Cl. CPC H01L 21/31116

(57) ABSTRACT

According to one embodiment, a method for manufacturing a semiconductor device includes placing a substrate having a to-be-processed layer on a stage within an etching chamber and supplying an etching gas into the etching chamber while keeping the stage at a first temperature to perform an etching treatment to etch the to-be-processed layer on the substrate by using a reactive ion etching method. After the etching treatment, and without exposing the substrate to the atmosphere, supplying an inert gas into the etching chamber while keeping the stage at a second temperature, which is higher than the first temperature, to perform a high-temperature treatment to heat the to-be-processed layer.

### CROSS-REFERENCE TO RELATED APPLICATION(S)

This application is based upon and claims the benefit of priority from Japanese Patent Application No. 2022-029922, filed Feb. 28, 2022, the entire contents of which are incorporated herein by reference.

### FIELD

Embodiments described herein relate generally to a method of manufacturing a semiconductor device.

### BACKGROUND

A method is known which involves etching of a processing object in the manufacturing of a semiconductor device.

### BRIEF DESCRIPTION OF THE DRAWINGS

FIG. 1 is a schematic configuration diagram of a reactive ion etching apparatus for use in a semiconductor device manufacturing process.

FIGS. 2A through 2D are diagrams illustrating aspects of a semiconductor device manufacturing method using a reactive ion etching apparatus.

FIG. 3 is a diagram illustrating aspects related to a semiconductor device manufacturing method using a reactive ion etching apparatus.

FIG. 4 is a schematic configuration diagram of another reactive ion etching apparatus for use in a semiconductor device manufacturing process.

FIG. 5 is a diagram illustrating aspects related to a semiconductor device manufacturing method using the reactive ion etching apparatus shown in FIG. 4.

### DETAILED DESCRIPTION

Embodiments provide a method for manufacturing a semiconductor device.

In general, according to one embodiment, a method for manufacturing a semiconductor device comprises etching a stacked film, composed of silicon oxide films and silicon nitride films which are stacked alternately, using a plasma of a process gas containing C, H and F, and heating the stacked film in a nitrogen atmosphere.

In general, according to another embodiment, a method for manufacturing a semiconductor device includes placing a substrate on a stage in an etching chamber and supplying an etching gas into the etching chamber while keeping the stage at a first temperature to perform an etching treatment to etch a layer on the substrate by using a reactive ion etching method. After the etching treatment, and without removing the substrate from the etching chamber, supplying an inert gas into the etching chamber while keeping the stage at a second temperature higher than the first temperature to perform a high-temperature treatment on the substrate.

Certain example of the present disclosure will now be described with reference to the drawings. To facilitate a better understanding of the drawings and the description below, the same reference symbols are used for the same or substantially similar components or elements in the drawings, and a duplicate description thereof may be omitted.

### First Embodiment

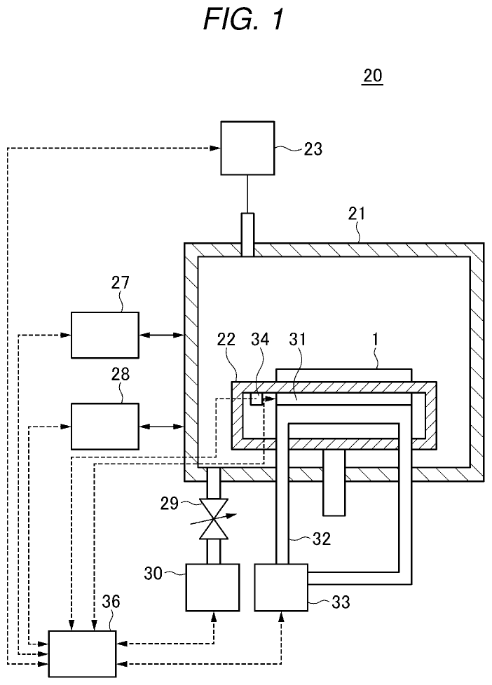

A reactive ion etching apparatus for a first embodiment will now be described with reference to FIG. 1. The reactive ion etching apparatus 20 includes an etching chamber 21, a stage 22, a gas supply unit 23, a first high-frequency power source 27, a second high-frequency power source 28, a variable conductance valve 29, a vacuum pump 30, a heater 31, a refrigerant passage 32, a refrigerant unit 33, a temperature sensor 34, and a controller 36.

The stage 22 is provided in the chamber 21. The stage 22 is configured to receive a wafer 1 on an upper surface of the like.

An etching gas and an inert gas are supplied from the gas supply unit 23 to the etching chamber 21.

The heater 31 is provided in the interior of the stage 22. The heater 31 functions to heat the stage 22. The temperature of the wafer 1 on the stage 22 can be raised by heating of the stage 22.

The refrigerant passage 32 is provided to pass through the interior of the stage 22. The refrigerant passage 32 is a hollow space within the stage. A refrigerant for cooling the stage 22 is supplied to the refrigerant passage 32. The refrigerant is, for example, a fluorine-containing inert liquid.

The first high-frequency power source 27 and the second high-frequency power source 28 function to apply a high-frequency (RF) power to the interior of the etching chamber 21. A plasma is generated in the etching chamber 21 by the high-frequency power applied to the etching chamber 21. A first high-frequency power applied by the first high-frequency power source 27 is, for example, not less than 50 W and not more than 20000 W. A first frequency applied by the first high-frequency power source 27 is, for example, not less than 20 MHz and not more than 200 MHz. A second high-frequency power applied by the second high-frequency power source 28 is, for example, not less than 50 W and not more than 20000 W. A second frequency applied by the second high-frequency power source 28 is lower than the first frequency and is, for example, not less than 0.1 MHz and not more than 20 MHz.

The refrigerant unit 33 is connected to the refrigerant passage 32. The refrigerant unit 33 circulates the refrigerant in the refrigerant passage 32.

The temperature sensor 34 is provided in the interior of the stage 22. The temperature sensor 34 monitors the temperature of the stage 22.

The vacuum pump 30 is connected via the variable conductance valve 29 to the etching chamber 21.

The controller 36 functions to control the operations of the gas supply unit 23, the first high-frequency power source 27, the second high-frequency power source 28, the variable conductance valve 29, and the vacuum pump 30.

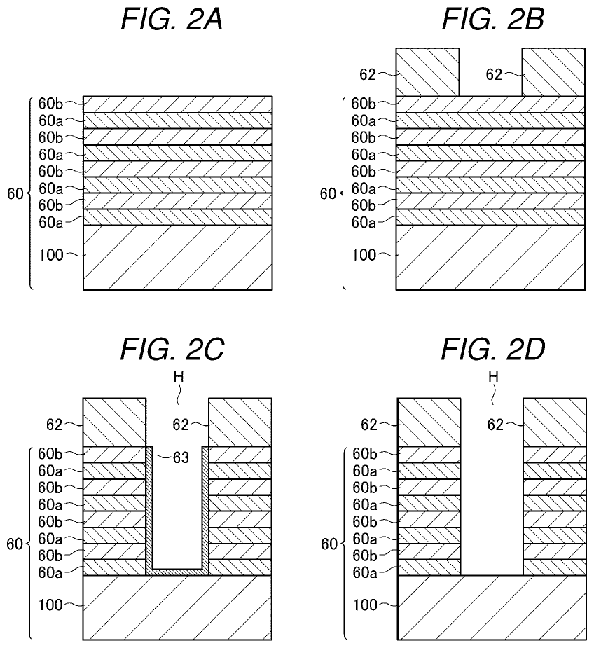

An example of a semiconductor device manufacturing method according to a first embodiment will now be described. FIGS. 2A through 2D are diagrams illustrating aspects of the example method according to the first embodiment.

First, a stacked body 60 is formed on a silicon substrate 100 (FIG. 2A). The silicon substrate 100 is a semiconductor wafer. The stacked body 60 is an insulating layer. The silicon substrate 100 is an example of a substrate. The stacked body 60 is an example of a so called “to-be-processed layer” (that is, a layer to be etched or otherwise processed in the reactive ion processing apparatus 20). The silicon substrate 100 is an example of a wafer 1 depicted in FIG. 1.

The stacked body 60 comprises a structure in which silicon oxide films 60a and silicon nitride films 60b are stacked alternately. The silicon oxide films 60a and the silicon nitride films 60b are formed, for example, by a chemical vapor deposition (CVD) method.

Next, a carbon layer 62 having a pattern of holes is formed on the stacked body 60 (FIG. 2B). The carbon layer 62 is a mask layer. The carbon layer 62 is formed, for example, by a sputtering method. The pattern of holes in the carbon layer 62 is formed, for example, by a lithography method and/or an RIE method.

A resist layer, an insulating layer, or a metal layer, for example, may also be used as a mask layer instead or, or in addition to, the carbon layer 62.

Next, the silicon substrate 100 is carried into the etching chamber 21. The silicon substrate 100 is placed on the stage 22 provided in the etching chamber 21.

In the etching chamber 21, holes H are formed by a reactive ion etching method using the carbon layer 62 as a mask (FIG. 2C). In the reactive ion etching, a reaction product 63 is formed on the stacked body 60. In the reactive ion etching, the reaction product 63 is formed or deposited on the bottom surfaces and side surfaces of the holes H.

The reaction product 63 comprises, for example, silicon (Si), nitrogen (N), and fluorine (F). In an example, the reaction product 63 comprises ammonium fluorosilicate ((NH₄)₂SiF₆).

Next, the silicon substrate 100 is heated in the etching chamber 21 to remove the reaction product 63 (FIG. 2D). The holes H are completed in this manner.

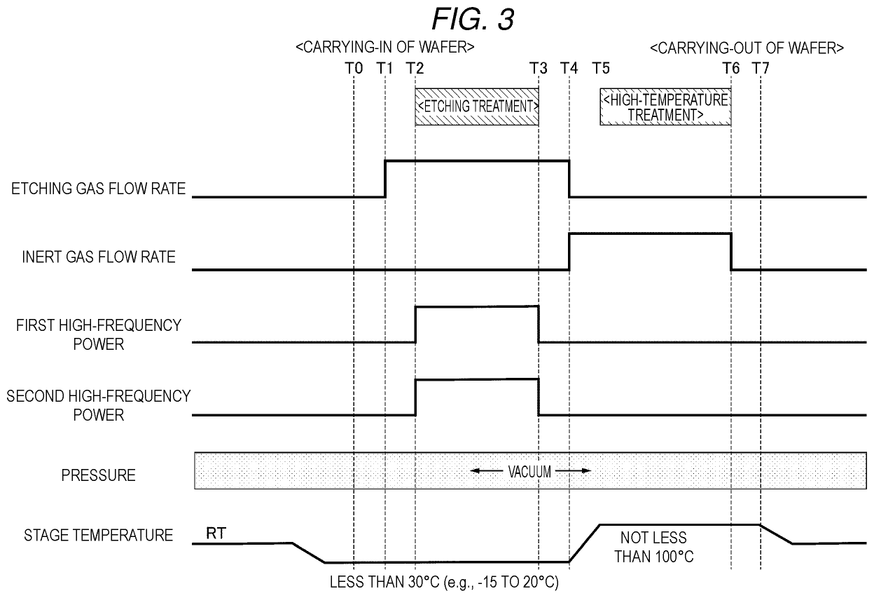

FIG. 3 shows relationships of the flow rate of the etching gas, the flow rate of the inert gas, the first high-frequency power, the second high-frequency power, and the temperature of the stage with processing time during the formation of the holes H in this embodiment.

At time T0, the silicon substrate 100 is carried into the etching chamber 21. At this time, the temperature of the stage 22 is less than 30° C. The temperature of the stage 22 is, for example, not more than 0° C. The temperature of the stage 22 is, for example, in a range of not less than −20° C. but not more than −10° C. The stage 22 can be kept at a desired temperature by circulating the refrigerant in the refrigerant passage 32 by means of the refrigerant unit 33.

At time T1, the supply of the etching gas into the etching chamber 21 is started. The etching gas contains, for example, carbon (C) and fluorine (F). The etching gas comprises, for example, CₓH_{y}F_{z} (where x is an integer equal to or greater than 1, y is an integer equal to or greater than 0, z is an integer equal to or greater than 1). The etching gas comprises, for example, C₄F₆, C₄F₈, or CH₂F₂.

At time T2, the application of a high-frequency power to the interior of the etching chamber 21 is started using the first high-frequency power source 27 and the second high-frequency power source 28.

The application of the high-frequency power from the first high-frequency power source 27 and the second high-frequency power source 28 is continued until time T3.

An etching treatment to etch the stacked body 60 is performed during the period from time T2 to time T3. The temperature of the stage 22 during the etching treatment may be referred to as a first temperature or an etching temperature.

At time T4, the supply of the etching gas into the etching chamber 21 is stopped. Furthermore, at time T4, the supply of the inert gas into the etching chamber 21 is started. The inert gas is, for example, nitrogen (N₂). In some examples, the inert gas comprises argon (Ar) or a mixture of inert gases.

The temperature of the stage 22 is raised to be not less than 100° C. at time T5. The temperature of the stage 22 can be, for example, not less than 200° C. but not more than 300° C. The use of the heater 31 can keep the stage 22 at a desired temperature.

At time T6, the supply of the inert gas into the etching chamber 21 is stopped.

A high-temperature treatment for heating the stacked body 60 is performed during the period from time T5 to time T6. The temperature of the stage 22 during the high-temperature treatment may be referred to as a second temperature or heat treatment temperature. The heat treatment temperature is higher than the etching temperature.

At time T7, the silicon substrate 100 is carried out of the etching chamber 21.

The interior of the etching chamber 21 is kept in a vacuum during the period from time TO (when the silicon substrate 100 is carried into the etching chamber 21) to time T7 (when the silicon substrate 100 is carried out of the etching chamber 21). Thus, the silicon substrate 100 is not exposed to the atmosphere during the period from the termination of the etching treatment to the termination of the high-temperature treatment.

The effects of the semiconductor device manufacturing method according to the first embodiment will now be described.

When etching is performed on a to-be-processed layer comprising silicon oxide films and silicon nitride films, a reaction product is sometimes formed on the to-be-processed layer. The reaction product is more likely to be formed when the etching is performed at a low temperature, e.g., at a temperature of less than 30° C. The reaction product is formed through a reaction between the etching gas and the to-be-processed layer. The reaction product can sometimes react with moisture in the air and grow as foreign matter on the side walls of the holes H. For example, when the reaction product comprises (NH₄)₂SiF₆, the (NH₄)₂SiF₆ can react with moisture in the air to form hydrogen fluoride (HF). The HF can etch the to-be-processed layer in an unintended manner.

The reaction product tends to be formed more in the vicinity of the silicon nitride films, and thus HF would be generated more near (or upon) the silicon nitride films. Accordingly, the side surfaces of the silicon nitride films are likely to be etched and recede more than the silicon oxide films.

In the formation of the holes H in the semiconductor device manufacturing method according to the first embodiment, the high-temperature treatment to heat the to-be-processed layer is performed in the etch chamber after the etching treatment. The (NH₄)₂SiF₆ decomposes at a temperature above 100° C. Therefore, the reaction product can be removed by heating to a temperature above 100° C.

The reaction product may sometimes contain ammonium fluoride (NH₄F) or a SiOₓF_{y} (where x is an integer equal to or greater than 1, y is an integer equal to or greater than 1). Ammonium fluoride (NH₄F) decomposes at a temperature above 40° C., and SiOₓF_{y} vaporizes at a temperature between −70° C. to 30° C. Therefore, such a reaction product can be removed by appropriately setting the temperature for the high-temperature treatment.

Thus, when the to-be-processed layer includes silicon nitride films, a reaction product including (NH₄)₂SiF₆, NH₄F and/or SiOₓF_{y} may be formed, but these reaction products can be removed by the high-temperature treatment following the etching treatment.

The to-be-processed layer, on which the reaction product has been formed after the etching treatment, is subjected to the high-temperature treatment without being exposed to the atmosphere at any point between the etching treatment and the high-temperature treatment. Thus, the layer is not significantly exposed to water vapor before removal of the reaction product(s). After removal of the reaction product, the generation of HF or the like is prevented, and thus etching of the side surfaces of the to-be-processed layer by HF generated by exposure of the reaction product to atmospheric moisture can be prevented.

### Second Embodiment

A semiconductor device manufacturing method according to a second embodiment differs from the first embodiment in the use of a reactive ion etching apparatus which includes a heating chamber for performing a high-temperature treatment separately from an etching chamber for performing an etching treatment.

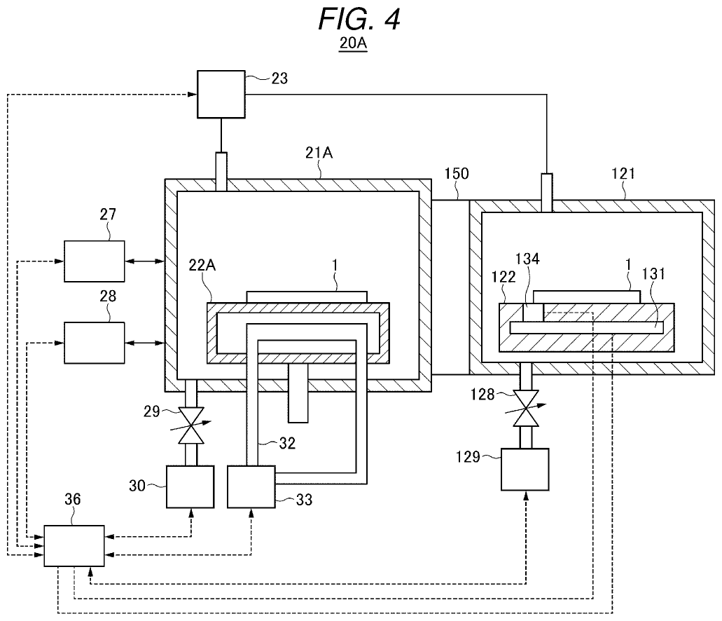

FIG. 4 is a schematic cross-sectional view of a reactive ion etching apparatus for use in the semiconductor device manufacturing method according to the second embodiment. The reactive ion etching apparatus 20A includes an etching chamber 21A and a heating chamber 121. The etching chamber 21A and the heating chamber 121 are connected by a wafer conveyance path 150. A wafer 1 can move between the etching chamber 21A and the heating chamber 121 through the wafer conveyance path 150.

A stage 22A is provided in the etching chamber 21A. The stage 22A corresponds in general to the stage 22, described above with reference to FIG. 1, but with the heater 31 and the temperature sensor 34 removed in this example.

A stage 122 is provided in the heating chamber 121. The stage 122 is configured to receive the wafer 1.

An inert gas is supplied from a gas supply unit 23 to the heating chamber 121.

A heater 131 is provided in the interior of the stage 122. The heater 131 functions to heat the stage 122. The temperature of the wafer 1 on the stage 122 is raised by heating the stage 122.

A temperature sensor 134 is provided in the interior of the stage 122. The temperature sensor 134 monitors the temperature of the stage 122.

A vacuum pump 129 is connected via a variable conductance valve 128 to the heating chamber 121.

The controller 36 functions to control the operations of the gas supply unit 23, the first high-frequency power source 27, the second high-frequency power source 28, the variable conductance valves 29, 128, and the vacuum pumps 30, 129.

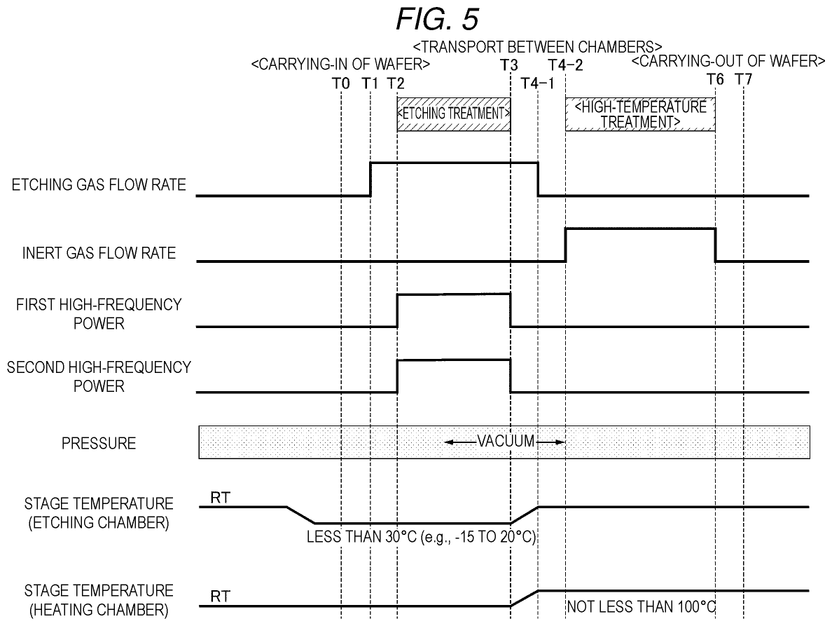

FIG. 5 shows relationships of the flow rate of the etching gas, the flow rate of the inert gas, the first high-frequency power, the second high-frequency power, the temperature of the stage in the etching chamber, and the temperature of the stage in the heating chamber with processing time in the second embodiment.

The method illustrated in FIG. 5, the process until stoppage of the supply of the etching gas into the etching chamber 21A at time T4-1, is substantially the same as the method of the first embodiment up until time T4.

After stopping the supply of the etching gas (at time T4-1), the wafer 1 is conveyed from the etching chamber 21A to the heating chamber 121. After carrying the wafer 1 into the heating chamber 121, the supply of the inert gas to the heating chamber 121 is started at time T4-2. The temperature of the stage 122 in the heating chamber 121 is not less than 100° C. at time T4-2. The temperature of the stage 122 is, for example, 200° C. to 300° C. The heater 131 can keep the stage 122 at a desired temperature.

At time T6, the supply of the inert gas into the heating chamber 121 is stopped.

A high-temperature treatment for heating the stacked body 60 is performed during the period from time T4-2 to time T6.

The etching chamber 21A, the heating chamber 121 and the wafer conveyance path 150 are kept in a vacuum. Thus, the silicon substrate 100 is not exposed to the atmosphere during the period from the termination of the etching treatment to the termination of the high-temperature treatment.

Thus, the to-be-processed layer, on which a reaction product has been formed during the etching, can be subjected to the high-temperature treatment without being exposed to the atmosphere. The high-temperature treatment can remove the reaction product, and the removal of the reaction product can prevent the growth of foreign matter on the side surfaces of the holes H upon exposure to the atmosphere. In addition, removal of the reaction product before atmospheric exposure can prevent the generation of HF, and can therefore prevent the HF from etching the side surfaces of the to-be-processed layer.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, comprising:
placing a substrate on a stage in an etching chamber;
supplying an etching gas into the etching chamber while keeping the stage at a first temperature to perform an etching treatment to etch a layer on the substrate by using a reactive ion etching method; and
after the etching treatment, without removing the substrate from the etching chamber, supplying an inert gas into the etching chamber while keeping the stage at a second temperature higher than the first temperature to perform a high-temperature treatment on the substrate.

2. The method according to claim 1, wherein the layer is a stacked layer of insulating films.

3. The method according to claim 1, wherein the layer is a plurality of silicon nitride films stacked alternately with a plurality of silicon oxide films.

4. The method according to claim 1, wherein the first temperature is 30° C. or less.

5. The method according to claim 4, wherein the second temperature is 100° C. or more.

6. The method according to claim 4, wherein the second temperature is in a range of 200° C. to 300° C.

7. The method according to claim 6, wherein the first temperature is 0° C. or less.

8. The method according to claim 1, wherein the second temperature is 100° C. or more.

9. The method according to claim 1, wherein a hole is etched in the layer during the etch treatment.

10. A method for manufacturing a semiconductor device, comprising:
placing a substrate on a first stage in an etching chamber;
supplying an etching gas into the etching chamber while keeping the first stage at a first temperature to perform an etching treatment to etch a layer on the substrate by using a reactive ion etching method; and
after the etching treatment, placing the substrate on a second stage in a heating chamber without exposing to the substrate to a non-vacuum environment after removal from the etching chamber; and
supplying an inert gas into the heating chamber while keeping the second stage at a second temperature higher than the first temperature to perform a high-temperature treatment on the substrate.

11. The method according to claim 10, wherein the layer is a stacked layer of insulating films.

12. The method according to claim 10, wherein the layer is a plurality of silicon nitride films stacked alternately with a plurality of silicon oxide films.

13. The method according to claim 10, wherein the first temperature is 30° C. or less.

14. The method according to claim 13, wherein the second temperature is 100° C. or more.

15. The method according to claim 13, wherein the second temperature is in a range of 200° C. to 300° C.

16. The method according to claim 15, wherein the first temperature is 0° C. or less.

17. The method according to claim 10, wherein the second temperature is 100° C. or more.

18. The method according to claim 10, wherein a hole is etched in the layer during the etch treatment.

19. A method for manufacturing a semiconductor device, comprising:
forming a stacked body of insulating films on a substrate;
placing the substrate on a stage in an etching chamber;
supplying an etching gas into the etching chamber while keeping the stage at a first temperature to perform an etching treatment to etch a hole in the stacked body on the substrate by using a reactive ion etching method; and
after the etching treatment, without removing the substrate from the etching chamber, supplying an inert gas into the etching chamber while keeping the stage at a second temperature higher than the first temperature to perform a high-temperature treatment on the substrate to remove a reaction product from a sidewall of the hole.

20. The method according to claim 19, wherein the insulating films are a plurality of silicon oxide films stacked alternately with a plurality of silicon nitride films.
